(19) United States
(12) Patent Application Publication
(10) Pub. No.: US 2024/0128321 A1
(43) Pub. Date: Apr. 18, 2024

(54) SEMICONDUCTOR DEVICE INCLUDING BLOCKING LAYER AND SOURCE/DRAIN STRUCTURE

(71) Applicant: SAMSUNG ELECTRONICS CO., LTD., Suwon-si (KR)

(72) Inventors: Jongryeol Yoo, Suwon-si (KR); Jungtaek Kim, Suwon-si (KR)

(73) Assignee: SAMSUNG ELECTRONICS CO., LTD., Suwon-si (KR)

(21) Appl. No.: 18/378,874

(22) Filed: Oct. 11, 2023

(30) Foreign Application Priority Data
Oct. 12, 2022 (KR) 10-2022-0130712

(51) Int. Cl. H01L 29/08; H01L 21/02; H01L 29/06; H01L 29/161; H01L 29/423; H01L 29/66; H01L 29/775

(52) U.S. Cl. CPC H01L 29/0847; H01L 21/02532; H01L 29/0673; H01L 29/161; H01L 29/42392; H01L 29/66439; H01L 29/66545; H01L 29/775

(57) ABSTRACT

A semiconductor device includes an active region including a first portion and a second portion; an isolation region on a side surface of the active region; a plurality of active layers stacked and spaced apart from each other in a vertical direction on the first portion of the active region; an epitaxial structure disposed on the second portion of the active region, connected to the plurality of active layers, and overlapping the isolation region in the vertical direction; a gate structure extending by intersecting the active region and surrounding each of the plurality of active layers; and a gate spacer on a side surface of the gate structure. The epitaxial structure includes a blocking layer and a source/drain structure on the blocking layer. The blocking layer includes a plurality of active blocking portions contacting the plurality of active layers, respectively, and at least one first bent portion bent and extending from at least one of the plurality of active blocking portions and contacting the gate spacer.

### CROSS-REFERENCE TO RELATED APPLICATION(S)

This application is based on and claims priority to Korean Patent Application No. 10-2022-0130712 filed on Oct. 12, 2022 in the Korean Intellectual Property Office, the disclosure of which is incorporated herein in its entirety by reference.

### BACKGROUND

Example embodiments of the present disclosure relate to a semiconductor device including a plurality of active layers, a blocking layer, and a source/drain structure.

As the demand for high performance, high speed, and/or multifunctionality of a semiconductor device has increased, integration density of a semiconductor device has also increased. In manufacturing a semiconductor device having a fine pattern corresponding to the trend for high integration of the semiconductor device, it has been necessary to implement patterns having a fine width or a fine spacing. Also, to address the limitations of operating properties due to the size reduction of a planar metal-oxide-semiconductor field-effect transistor (MOSFET), there have been attempts to develop a semiconductor device including a fin field-effect transistor (FinFET) having a three-dimensional channel structure.

### SUMMARY

Example embodiments of the disclosure provide a semiconductor device which may prevent a leakage current in a transistor including a plurality of active layers vertically spaced apart from each other.

According to an embodiment, there is provided a semiconductor device which may include: an active region including a first portion and a second portion; an isolation region on a side surface of the active region; a plurality of active layers stacked and spaced apart from each other in a vertical direction and on the first portion of the active region; an epitaxial structure disposed on the second portion of the active region, connected to the plurality of active layers, and overlapping the isolation region in the vertical direction; a gate structure extending while intersecting the active region and surrounding each of the plurality of active layers; and a gate spacer on a side surface of the gate structure. The epitaxial structure includes a blocking layer and a source/drain structure on the blocking layer. The blocking layer includes a plurality of active blocking portions contacting the plurality of active layers, respectively, and at least one first bent portion bent and extending from at least one of the plurality of active blocking portions and contacting the gate spacer.

According to an embodiment, there is provided a semiconductor device which may include: an active region including a first portion and a second portion; an isolation region on a side surface of the active region; a plurality of active layers stacked and spaced apart from each other in a vertical direction and on the first portion of the active region; an epitaxial structure disposed on the second portion of the active region, connected to the plurality of active layers, and overlapping the isolation region in the vertical direction; a gate structure extending while intersecting the active region and surrounding each of the plurality of active layers; and a gate spacer on a side surface of the gate structure. The gate structure includes a plurality of lower gate portions disposed below the plurality of active layers, respectively, and an upper gate portion disposed on an upper active layer among the plurality of active layers. The epitaxial structure includes a blocking layer and a source/drain structure on the blocking layer. The blocking layer includes a lower blocking portion contacting the second portion of the active region, a plurality of active blocking portions contacting the plurality of active layers, respectively, a plurality of gate blocking portions contacting the lower gate portions, respectively, and at least one bent portion bent and extending from at least one of the plurality of active blocking portions, the plurality of gate blocking portions, and the lower blocking portion, and contacting the gate spacer.

According to an embodiment, there is provided a semiconductor device which may include: an active region including a first portion and a second portion; a plurality of active layers stacked and spaced apart from each other in a vertical direction and on the first portion of the active region; an epitaxial structure disposed on the second portion of the active region and electrically connected to the plurality of active layers; a gate structure extending while intersecting the active region and surrounding each of the plurality of active layers; and a gate spacer on a side surface of the gate structure. The gate structure includes a plurality of lower gate portions disposed below the plurality of active layers, respectively, and an upper gate portion disposed on an upper active layer among the plurality of active layers. The epitaxial structure includes a blocking layer and a source/drain structure on the blocking layer. The blocking layer includes a lower blocking portion contacting the second portion of the active region, a plurality of active blocking portions contacting the plurality of active layers, respectively, a plurality of gate blocking portions contacting the lower gate portions, respectively, and at least one bent portion bent and extending horizontally from at least one of the plurality of active blocking portions and the plurality of gate blocking portions and contacting the gate spacer.

### BRIEF DESCRIPTION OF DRAWINGS

The above and other aspects, features, and advantages of the disclosure will be more clearly understood from the following detailed description, taken in combination with the accompanying drawings, in which:

FIGS. 1 to 5 illustrate a semiconductor device, according to embodiments;

FIG. 6 is an enlarged cross-sectional diagram illustrating a modified example of the semiconductor device of FIG. 1, according to an embodiment;

FIG. 7 is an enlarged cross-sectional viws illustrating the modified example of the semiconductor device of FIG. 1, according to an embodiment;

FIG. 8 is an enlarged cross-sectional view of a modified example of the semiconductor device of FIG. 1 in a plan view, illustrating a modified component of FIG. 4, according to an embodiment;

FIG. 9 is an enlarged cross-sectional view of a modified example of the semiconductor device of FIG. 1 in a plan view, illustrating a modified component of FIG. 5, according to an embodiment; and

FIGS. 10A and 10B are flow charts illustrating an example of a method of manufacturing a semiconductor device, according to an embodiment, and FIGS. 11A-11B to 15A-15B are cross-sectional views illustrating a method of forming the semiconductor device shown in FIG. 1 taken along lines I-I′ and respectively, according to embodiments.

### DETAILED DESCRIPTION

Hereinafter, embodiments of the present disclosure will be described as follows with reference to the accompanying drawings.

Hereinafter, spatially relative terms such as “upper,” “middle,” “lower”, “vertical”, “horizontal”, and/or the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. Terms such as “first,” “second,” and “third” may be used to describe various elements. These terms are used to distinguish one element from another element, but the elements are not otherwise limited by the terms. For example, a “first element” may be termed a “second element” without departing from the scope of the disclosure. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

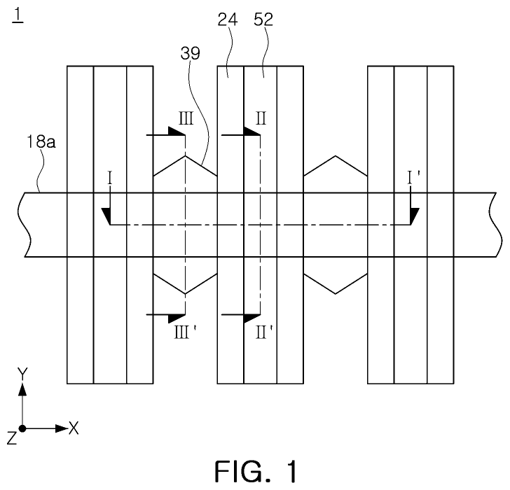

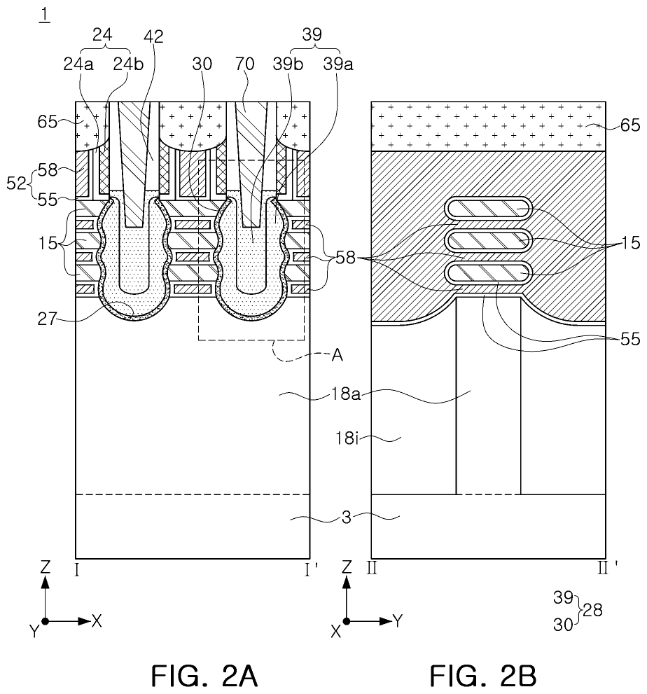

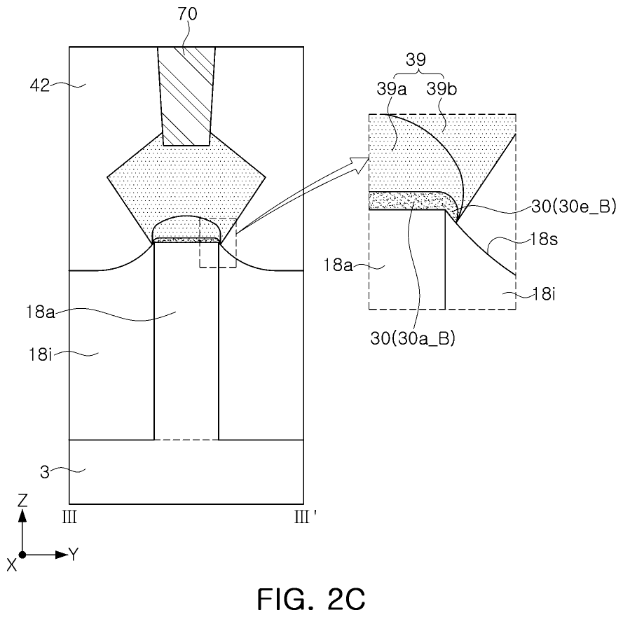

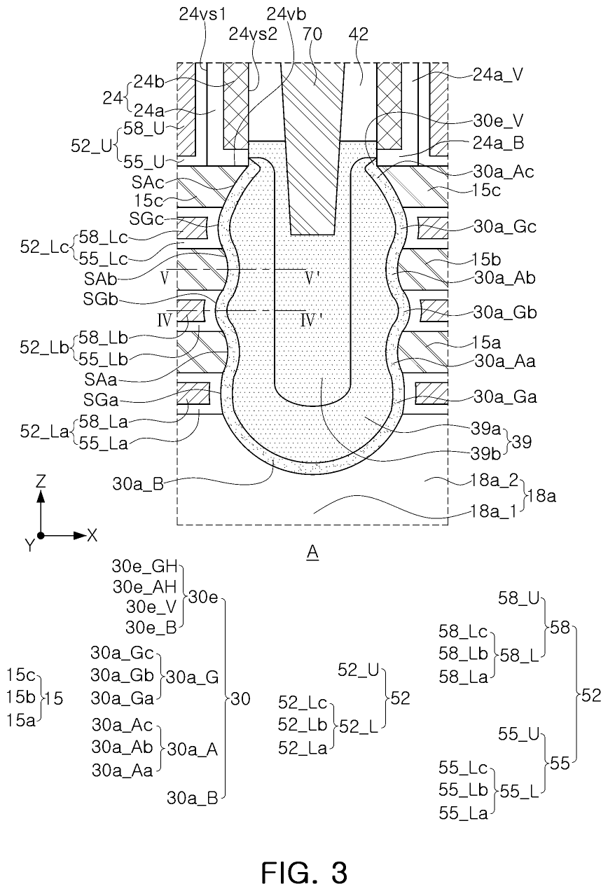

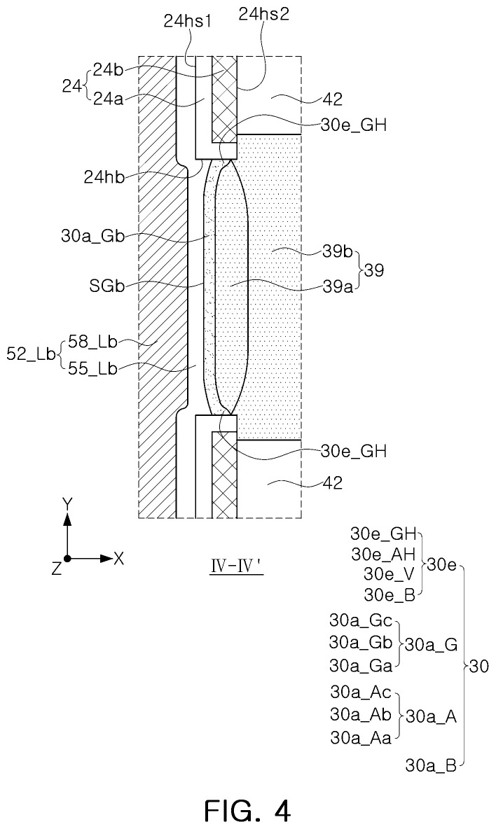

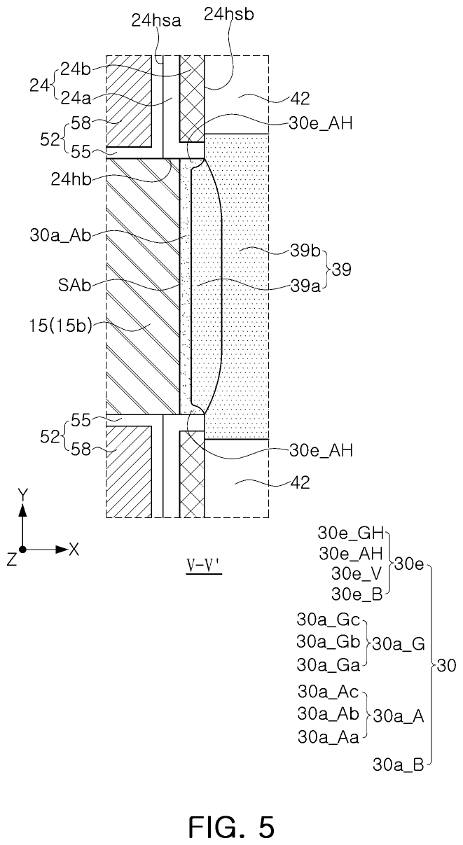

FIGS. 1 to 5 illustrate a semiconductor device, according to embodiments. FIG. 1 is a top plan view of a semiconductor device, according to an embodiment. FIG. 2A is a cross-sectional view of the semiconductor device shown in FIG. 1 taken along a line I-I′, according to an embodiment. FIG. 2B is a cross-sectional view of the semiconductor device shown in FIG. 1 taken along a line according to an embodiment. FIG. 2C is a cross-sectional view of the semiconductor device shown in FIG. 1 taken along a line according to an embodiment. FIG. 3 is an enlarged view of a portion “A” shown in FIG. 2A, according to an embodiment. FIG. 4 is a plan view of the semiconductor device of FIG. 1 at a plane taken along a line IV-IV′ in FIG. 3 in an X-Y horizontal direction. FIG. 5 is a plan view of the semiconductor device of FIG. 1 at a plane taken along a line V-V′ in FIG. 3 in an X-Y horizontal direction.

It is understood here that FIG. 1 illustrates a structural and positional relationship between an active region, a gate structure, a gate spacer and a source/drain structure of a semiconductor device without showing all other structural elements of the semiconductor device for brevity purposes.

Referring to FIGS. 1, 2A-2B and 3, a semiconductor device 1 according to an embodiment may include a substrate 3, an active region 18a on the substrate 3, and an isolation region 18i disposed on a side surface of the active region 18a on the substrate 3.

The substrate 3 may include a semiconductor material, for example, a group IV semiconductor, a group III-V compound semiconductor, or a group II-VI compound semiconductor. For example, the group IV semiconductor may include silicon, germanium, or silicon-germanium. The substrate 3 may be provided as a bulk wafer, an epitaxial layer, a silicon on insulator (SOI) layer, or a semiconductor on insulator (SeOI) layer.

The isolation region 18i may be formed of an insulating material. For example, the isolation region 18i may include a low-κ dielectric, silicon oxide, silicon nitride, or another oxide or nitride compound, not being limited thereto. The isolation region 18i may be formed using a shallow trench isolation (STI) process.

The active region 18a may be an active fin extending from the substrate 3 in a vertical direction Z. The vertical direction Z may be a direction perpendicular to an upper surface of the substrate 3. The active region 18a may have a bar shape or a line shape extending in the first horizontal direction X, which is a channel-length direction, in the top plan view. The first horizontal direction X may be parallel to the upper surface of the substrate 3.

The active region 18a may include the same material as that of the substrate 3, for example, a semiconductor material. The active region 18a may include a well region. For example, when the active region 18a is to form a p-type metal-oxide-semiconductor (PMOS) transistor, the active region 18a may include an n-type well region including impurities such as phosphorus (P), arsenic (As) or antimony (Sb). Alternatively, when the active region 18a is to form an n-type metal-oxide-semiconductor (NMOS) transistor, the active region 18a may include a p-type well region including impurities such as boron (B), gallium (Ga) or indium (In). The active region 18a may include a first portion 18a_1 and a second portion 18a_2.

The semiconductor device 1 may further include a plurality of active layers 15 stacked and spaced apart from each other in the vertical direction Z above the second portion 18a_2 of the active region 18a. For example, the plurality of active layers 15 may include a lower active layer 15a, an intermediate active layer 15b on the lower active layer 15a, and an upper active layer 15c on the intermediate active layer 15b. FIGS. 2A-2B and 3 show that the plurality of active layers 15 include three active layers, the lower, intermediate, and upper active layers 15a, 15b, and 15c, but the disclosure is not limited thereto. For example, the plurality of active layers 15 may include more or less than three active layers spaced apart from each other in the vertical direction Z, according to embodiments.

The plurality of active layers 15 may include a semiconductor material which may be used as a channel region of a transistor, for example, a silicon material. For example, each of the plurality of active layers 15 may include a semiconductor layer, for example, a silicon layer. The plurality of active layers 15 may be referred to as channel layers.

The semiconductor device 1 may include a gate structure 52 extending in a second horizontal direction Y, which is a channel-width direction, while intersecting the active region 18a and surrounding the plurality of active layers 15, respectively, a gate capping pattern 65 on the gate structure 52, and a gate spacer 24 on the side surface of the gate structure 52. The gate structure 52 may intersect the active region 18a and may extend in the second horizontal direction Y. Accordingly, the gate structure 52 may include a portion vertically overlapping the active region 18a and a portion vertically overlapping the isolation region 18i.

The gate structure 52 may include a gate dielectric layer 55 and a gate electrode 58 on the gate dielectric layer 55. The gate dielectric layer 55 may include at least one of silicon oxide and a high-K dielectric. The high-K material may refer to a dielectric material having a dielectric constant higher than that of silicon oxide (e.g., SiO₂). The high-κ material may be one of, for example, aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (Pr₂O₃).

The gate electrode 58 may include a conductive material. For example, the gate electrode 58 may include doped polysilicon, a metal, conductive metal nitride, a metal-semiconductor compound, conductive metal oxide, conductive graphene, conductive carbon nanotube, or a combination thereof. For example, the gate electrode 58 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOₓ, RuOₓ, conductive graphene, conductive carbon nanotube, or a combination thereof, but the disclosure is not limited thereto. The gate electrode 58 may include a single layer or multiple layers formed of the aforementioned materials.

The gate structure 52 may include lower gate portions 52_L disposed below each of the plurality of active layers 15 and an upper gate portion 52_U disposed above an uppermost active layer among the plurality of active layers 15. For example, in the gate structure 52, the lower gate portions 52_L may include a first lower gate portion 52_La between the active region 18a and the lower active layer 15a, a second lower gate portion 52_Lb between the lower active layer 15a and the intermediate active layer 15b, and a third lower gate portion 52_Lc between the intermediate active layer 15b and the upper active layer 15c.

In the cross-sectional structure taken along the first horizontal direction X, for example, the I-I′ cross-sectional structure in FIG. 2A and the enlarged cross-sectional structure in FIG. 3, each of the lower gate portions 52_L of the gate structure 52 may include a lower gate electrode portion 58_L and a lower gate dielectric portion 55_L surrounding the lower gate electrode portion 58_L, and the upper gate portion 52_U of the gate structure 52 may include an upper gate electrode portion 58_U and an upper gate dielectric portion 55_U disposed on the lower surface and side surfaces of the upper gate electrode portion 58_U. For example, the lower gate portion 58_L may include lower gate electrode portions 58_La, 58_Lb, and 58_Lc, and the lower gate dielectric portion 55_L may include lower gate dielectric portions 55_La, 55_Lb, and 55_Lc surrounding a lower surface, an upper surface and side surfaces of the lower gate electrode portions 58_La, 58_Lb, and 58_Lc, respectively.

The gate spacer 24 may be formed of an insulating material. For example, the gate spacer 24 may include a low-ic dielectric, silicon oxide, silicon nitride, silicon oxynitride (SiON), or a combination thereof, not being limited thereto. For example, the gate spacer 24 may include multiple layers formed of the materials described above. For example, the gate spacer 24 may include a first spacer 24a and a second spacer 24b. The first spacer 24a may include a first material, the second spacer 24b may include a second material different from the first material. For example, the first material of the first spacer 24a may include at least one of a low-ic dielectric and silicon oxide, the second material of the second spacer 24b may include at least one of silicon nitride and silicon oxynitride (SiON). The first spacer 24a may include a vertical portion 24a V interposed between the upper gate portion 52_U and the second spacer 24b in the first horizontal direction X, and a lower portion 24a B interposed between the second spacer 24b and the upper active layer 15c in the vertical direction Z. Herein, the lower portion 24a B may also be referred to as a horizontal portion.

The gate capping pattern 65 may be disposed on the gate structure 52 and the gate spacer 24. The gate capping pattern 65 may include an insulating material such as silicon nitride, not being limited thereto.

The semiconductor device 1 may further include epitaxial structures 28, an interlayer insulating layer 42, and a contact plug 70. The epitaxial structures 28 may include portions disposed above the first portion 18a_1 of the active region 18a, connected to the plurality of active layers 15, and overlapping the isolation region 18i in the vertical direction Z. For example, the epitaxial structures 28 may partially overlap the isolation region 18i in the vertical direction Z. The epitaxial structures 28 may be electrically connected to the plurality of active layers 15. The interlayer insulating layer 42 may be disposed on side surfaces of the gate spacer 24, the gate capping pattern 65 and the upper gate portion 52U. The interlayer insulating layer 42 may be disposed above the epitaxial structures 28. The interlayer insulating layer 42 may be disposed above the isolation region 18i. The contact plug 70 may penetrate through the interlayer insulating layer 42 and may be electrically connected to the epitaxial structures 28. The contact plug 70 may be formed of a conductive material.

The epitaxial structures 28 may include a blocking layer 30 and a source/drain structure 39 on the blocking layer 30.

The source/drain structure 39 may include a first source/drain epitaxial layer 39a and a second source/drain epitaxial layer 39b on the first source/drain epitaxial layer 39a. The first source/drain epitaxial layer 39a may include a first SiGe material, and the second source/drain epitaxial layer 39b may include a second SiGe material having a composition different from that of the first SiGe material. For example, the Ge concentration of the second SiGe material may be higher than the Ge concentration of the first SiGe material.

The source/drain structure 39 may be a source/drain region of a transistor. For example, in a PMOS transistor, the source/drain structure 39 may have p-type conductivity by including impurities such as boron (B).

The contact plug 70 may contact and electrically connected to the second source/drain epitaxial layer 39b.

The blocking layer 30 may include an epitaxial layer. The blocking layer 30 may have a material composition different from the source/drain structure 39. According to an embodiment, the blocking layer 30 may be configured as a silicon epitaxial layer. The blocking layer 30 may be a single crystal silicon layer. The blocking layer 30 may include a material having a composition different from that of the source/drain structure 39. For example, the source/drain structure 39 may include a SiGe epitaxial layer, and the blocking layer 30 may include an epitaxial layer different from the SiGe epitaxial layer, for example, a silicon epitaxial layer. According to an embodiment, when the source/drain structure 39 is formed of silicon (Si) or SiGe and doped with one or more impurities such as P, As, Sb, B, Ga, In, etc., the blocking layer may be formed of Si without one or more of the impurities.

In an example, the blocking layer 30 may include a doped epitaxial layer, for example, a doped silicon layer.

The blocking layer 30 may include a doped epitaxial layer doped with at least one of carbon (C), oxygen (O), nitrogen (N), or fluorine (F), for example, a doped silicon layer doped with at least one of carbon (C), oxygen (O), nitrogen (N), and fluorine (F).

The blocking layer 30 may include a doped epitaxial layer, for example, a doped silicon layer, including impurities doped by diffusion of impurities in the source/drain region of the transistor, for example, the source/drain structure 39. For example, a maximum concentration of impurities in the doped silicon layer of the blocking layer 30 may be lower than a maximum concentration of impurities in the source/drain region of a transistor, for example, the source/drain structure 39. For example, when the source/drain structure 39 adjacent to the blocking layer 30 is doped with boron, the blocking layer 30 may also be doped with boron, and a maximum concentration of boron in the blocking layer 30 may be lower than a maximum concentration of boron in the source/drain structure 39.

The blocking layer 30 may include a doped silicon layer including at least one of C, O, N, F and B (boron).

As another example, at least a portion of the blocking layer 30 may include an undoped epitaxial layer, for example, an undoped silicon layer. For example, the blocking layer 30 may be doped with the same impurities as impurities in the source/drain structure 39 in a portion adjacent to the source/drain structure 39, and may not be doped with the impurities in a portion spaced apart or distant from the source/drain structure 39.

The blocking layer 30 may have a thickness ranging from about 1 nm to about 5 nm. For example, to prevent a leakage current between the source/drain structure 39 and the gate electrode 58, the blocking layer 30 may have a thickness of about 1 nm or more, and the blocking layer 30 may have a thickness of about 5 nm or less to prevent electrical properties of the semiconductor device 1 from deteriorating as a size of the source/drain structure 39, for example, volume, decreases.

The first source/drain epitaxial layer 39a of the source/drain structure 39 may be disposed between the blocking layer 30 and the second source/drain epitaxial layer 39b. The first source/drain epitaxial layer 39a may have a thickness greater than that of the blocking layer 30.

In the enlarged cross-sectional view of FIG. 3, the gate spacer 24 may include a lower surface 24vb, an internal side surface 24vs1, and an external side surface 24vs2. The lower surface 24vb of the gate spacer 24 may contact the upper surface of the upper active layer 15c, and the internal side surface 24vs1 of the gate spacer 24 may contact the upper gate dielectric portion 55U of the upper gate portion 52_U, and the external side surface 24vs of the gate spacer 24 may be opposite to the internal side surface 24vs1 of the gate spacer 24 in the first horizontal direction X.

The blocking layer 30 may include a plurality of active blocking portions 30a_A contacting the plurality of active layers 15, a lower blocking portion 30a_B contacting the active region 18a, and a plurality of gate blocking portions 30a_G contacting the lower gate portions 52_L.

The blocking layer 30 may further include at least one bent portion 30e bent and extending from at least one of the plurality of active blocking portions 30a_A, the plurality of gate blocking portions 30a_G, and the lower blocking portion 30a_B, and contacting the gate spacer 24.

In the blocking layer 30, the plurality of active blocking portions 30a_A, the plurality of gate blocking portions 32a_G, the lower blocking portion 30a_B, and the at least one bent portion 30e may be integrated with each other. In the blocking layer 30, the plurality of active blocking portions 30a_A, the plurality of gate blocking portions 32a_G, the lower blocking portion 30a_B, and the at least one bent portion 30e may be formed as a continuously connected and integrated single layer or structure.

The plurality of active blocking portions 30a_A may include a lower active blocking portion 30a_Aa, an intermediate active blocking portion 30a_Ab on the lower active blocking portion 30a_Aa, and an upper active blocking portion 30a_Ac on the intermediate active blocking portion 30a_Ab. The lower active blocking portion 30a_Aa may be disposed at the same or substantially the same level as a level of the lower active layer 15a and may contact the lower active layer 15a. The intermediate active blocking portion 30a_Ab may be disposed at the same or substantially the same level as a level of the intermediate active layer 15b and may contact the intermediate active layer 15b. The upper active blocking portion 30a_Ac may be disposed at the same or substantially the same level as a level of the upper active layer 15c and may contact the upper active layer 15c.

The plurality of gate blocking portions 30a_G may include a lower gate blocking portion 30a_Ga, an intermediate gate blocking portion 30a_Gb on the lower gate blocking portion 30a_Ga, and an upper gate blocking portion 30a_Gc on the intermediate gate blocking portion 30a_Gb. The lower gate blocking portion 30a_Ga may be disposed at the same or substantially the same level as a level of the first lower gate portion 52_La and may contact the lower gate dielectric portion 55_La of the first lower gate portion 52_La. The intermediate gate blocking portion 30a_Gb may be disposed at the same or substantially the same level as a level of the second lower gate portion 52_Lb and may contact the lower gate dielectric portion 55_Lb of the second lower gate portion 52_Lb. The upper gate blocking portion 30a_Gc may be disposed at the same or substantially the same level as a level of the third lower gate portion 52_Lc and may contact the lower gate dielectric portion 55_Lc of the third lower gate portion 52_Lc.

In the cross-sectional structure illustrated in FIG. 3, at least a portion of the plurality of active blocking portions 30a_A may be bent in a direction toward a vertical central axis of the source/drain structure 39, and a portion of the plurality of gate blocking portions 30a_G may be bent in a direction away from a vertical central axis of the source/drain structure 39.

The at least one bent portion 30e of the blocking layer 30 may include at least one first bent portion extending from at least one of the plurality of active blocking portions 30a_A. For example, in the cross-sectional structure illustrated in FIG. 3, the at least one bent portion 30e of the blocking layer 30 may include a vertical bent portion 30e_V bent and extending from the upper active blocking portion 30a_Ac among the plurality of active blocking portions 30a_A and contacting the external side surface 24vs2 of the gate spacer 24. The vertical bent portion 30e_V may contact a side surface of the first spacer 24a of the gate spacer 24 and may be spaced apart from the second spacer 24b.

In the cross-sectional structure illustrated in FIG. 3, the vertical bent portion (30e_V in FIG. 3) may contact at least a half of the side surface of the first spacer 24a in the external side surface 24vs2 of the gate spacer 24, and may be spaced apart from the side surface of the second spacer 24b.

In the cross-sectional structure illustrated in FIG. 3, the side surface of the first spacer 24a in the external side surface 24vs2 of the gate spacer 24 may contact the second source/drain epitaxial layer 39b and the vertical bent portion 30e_V of the source/drain structure 39. In the cross-sectional structure illustrated in FIG. 3, the second source/drain epitaxial layer 39b of the source/drain structure 39 may contact a portion of the side surface of the first spacer 24a and a portion of the side surface of the second spacer 24b in the external side surface 24vs2 of the gate spacer 24.

In the cross-sectional structure illustrated in FIG. 3, a lower surface of the contact plug 70 may be disposed on a level lower than a level of the vertical bent portion 30e_V. In the cross-sectional structure illustrated in FIG. 3, the lower surface of the contact plug 70 may be disposed on a level lower than a level of the upper active layer 15c.

In the cross-sectional structure illustrated in FIG. 2C, the at least one bent portion 30e of the blocking layer 30 may further include a lower bent portion 30e_B bent and extending from the lower blocking portion 30a_B and contacting the upper surface 18s of the isolation region 18i. A level of a portion of the upper surface 18s of the isolation region 18i may be lowered in a direction away from the side surface of the active region 18a. A lower end portion (e.g., the lowermost end portion) of the lower bent portion 30e_B may be disposed on a level lower than a level of the lower blocking portion 30a_B.

An end portion of the at least one bent portion 30e of the blocking layer 30 may have a pointed shape.

The at least one bent portion 30e of the blocking layer 30 may prevent a leakage current that may be generated between the gate electrode 58 and the source/drain structure 39, or may prevent an electrical short that may be generated between the gate electrode 58 and the source/drain structure 39. For example, the at least one bent portion 30e (e.g., the vertical vent portion 30e_V) of the blocking layer 30 may prevent a leakage current or electrical short that may be generated along the lower surface of the gate spacer 24 between the upper gate electrode portion 58_U and the source/drain structure 39.

In the description below, a top plan view illustrating one of the lower gate portions 52_L, for example, the second lower gate portion 52_Lb among the lower gate portions 52_L will be described with reference to FIG. 4.

Referring to FIG. 4 together with FIGS. 1 to 3, in the top plan view, the gate spacer 24 may have a first side surface 24hsa contacting the gate dielectric layer 55, a second side surface 24hsb opposite to the first side surface 24hsa, and a third side surface 24hb extending from the end portions of the first and second side surfaces 24hsa and 24hsb, connecting the end portion to each other, and contacting the blocking layer 30. In the gate spacer 24, the first and second side surfaces 24hsa and 24hsb may be side surfaces disposed in the first horizontal direction X, and the third side surface 24hb may be a side surface disposed in the second horizontal direction Y.

The lower gate blocking portion 30a_Ga may have a side surface SGa (in FIG. 3) contacting the lower gate dielectric portion 55_La of the first lower gate portion 52_La, the intermediate gate blocking portion 30a_Gb may have a side surface SGb (in FIGS. 3 and 4) contacting the lower gate dielectric portion 55_Lb of the second lower gate portion 52_Lb, and the upper gate blocking portion 30a_Gc may have a side surface SGc (in FIG. 3) contacting the lower gate dielectric portion 55_Lc of the third lower gate portion 52_Lc.

The at least one bent portion 30e may further include at least one first horizontal bent portion 30e_GH bent and extending (e.g., bent and extending horizontally) from at least one of the gate blocking portions 30a_G. For example, the at least one first horizontal bent portion 30e_GH may include a first lower horizontal bent portion bent and extending from the lower gate blocking portion 30a_Ga, a first intermediate horizontal bent portion bent and extending from the intermediate gate blocking portion 30a_Gb, and a first upper horizontal bent portion bent and extending from the upper gate blocking portion 30a_Gc.

In the at least one first horizontal bent portion 30e_GH, the first lower horizontal bent portion and the first upper horizontal bent portion may have substantially the same planar shape as that of the first intermediate horizontal bent portion, and thus, the first intermediate horizontal bent portion will be described.

The first side surface 24hsa of the gate spacer 24 may contact the gate dielectric layer 55, for example, at least the lower gate dielectric portion 55_Lb of the second lower gate portion 52_Lb (in FIG. 4).

The first intermediate horizontal bent portion of the at least one first horizontal bent portion 30e_GH may be bent and extending from an end portion of the intermediate gate blocking portion 30a_Gb, may contact the third side surface 24hb of the gate spacer 24 and may be spaced apart from the second side surface 24hsb of the gate spacer 24. The first intermediate horizontal bent portion of the at least one first horizontal bent portion 30e_GH may not contact the second side surface 24hsb of the gate spacer 24.

The third side surface 24hb of the gate spacer 24 may contact the lower gate dielectric portion 55_Lb of the second lower gate portion 52_Lb, the intermediate gate blocking portion 30a_Gb, and the at least one first horizontal bent portion 30e_GH (e.g., the first intermediate horizontal bent portion).

The first intermediate horizontal bent portion of the at least one first horizontal bent portion 30e_GH may increase a distance between the lower gate electrode portion 58_Lb of the second lower gate portion 52_Lb and the source/drain structure 39 in the third side surface 24hb of the gate spacer 24. Accordingly, the first intermediate horizontal bent portion of the at least one first horizontal bent portion 30e_GH may prevent a leakage current between the lower gate electrode portion 58_Lb of the second lower gate portion 52_Lb and the source/drain structure 39, that may be generated on the third side surface 24hb of the gate spacer 24, or electrical short between the lower gate electrode portion 58_Lb of the second lower gate portion 52_Lb and the source/drain structure 39, that may be generated on the third side surface 24hb of the gate spacer 24.

According to an embodiment, the at least one first horizontal bent portion 30e_GH may prevent a leakage current between the lower gate electrode portions 58_La, 58_Lb, and 58_Lc of the lower gate portions 52_L and the source/drain structure 39, that may be generated on the third side surface 24hb of the gate spacer 24, or electrical short between the lower gate electrode portions 58_La, 58_Lb, and 58_Lc of the lower gate portions 52_L and the source/drain structure 39, that may be generated on the third side surface 24hb of the gate spacer 24.

The second source/drain epitaxial layer 39b of the source/drain structure 39 may contact a portion of the third side surface 24hb of the gate spacer 24, and may contact a portion of the second side surface 24hsb of the gate spacer 24.

In the description below, a top plan view illustrating one active layer of the plurality of active layers 15, for example, the intermediate active layer 15b among the plurality of active layers 15, will be described with reference to FIG. 5.

Referring to FIG. 5 together with FIGS. 1 to 4, as described with reference to FIG. 4, in the top plan view, the gate spacer 24 may include the first side surface 24hsa, the second side surface 24hsb, and the third side surface 24hb.

The lower active blocking portion 30a_Aa may have a side surface (SAa in FIG. 3) contacting the lower active layer 15a, the intermediate active blocking portion 30a_Ab may have a side surface SAb (in FIGS. 3 and 5) contacting the intermediate active layer 15b, and the upper active blocking portion 30a_Ac may have a side surface SAc (in FIG. 3) contacting the upper active layer 15c.

The at least one bent portion 30e may include at least one second horizontal bent portion 30e_AH bent and extending (e.g., bent and extending horizontally) from at least one of the active blocking portions 30a_A. For example, the at least one second horizontal bent portion 30e_AH may include a second lower horizontal bent portion bent and extending from the lower active blocking portion 30a_Aa, a second intermediate horizontal bent portion bent and extending from the intermediate active blocking portion 30a_Ab, and a second upper horizontal bent portion bent and extending from the upper active blocking portion 30a_Ac.

In the at least one second horizontal bent portion 30e_AH, the second lower horizontal bent portion and the second upper horizontal bent portion may have substantially the same planar shape as that of the second intermediate horizontal bent portion, and thus, the second intermediate horizontal bent portion will be mainly described.

In the cross-sectional view of FIG. 5, the second intermediate horizontal bent portion of the at least one second horizontal bent portion 30e_AH may be bent and extend from an end portion of the intermediate active blocking portion 30a_Ab, may contact the third side surface 24hb of the gate spacer 24 and may be spaced apart from the second side surface 24hsb of the gate spacer 24. The second intermediate horizontal bent portion of the at least one second horizontal bent portion 30e_AH may not contact the second side surface 24hsb of the gate spacer 24.

The third side surface 24hb of the gate spacer 24 may contact the intermediate active layer 15b, the intermediate active blocking portion 30a_Ab, and the at least one second horizontal bent portion 30e_AH (e.g., the second intermediate horizontal bent portion).

The second intermediate horizontal bent portion of the at least one second horizontal bent portion 30e_AH may increase a distance between the gate electrode 58 and the source/drain structure 39 on the third side surface 24hb of the gate spacer 24.

Accordingly, the at least one second horizontal bent portion 30e_AH may prevent a leakage current between the gate electrode 58 and the source/drain structure 39, that may be generated on the third side surface 24hb of the gate spacer 24, and electrical short between the gate electrode 58 and the source/drain structure 39, that may be generated on the third side surface 24hb of the gate spacer 24.

The second source/drain epitaxial layer 39b of the source/drain structure 39 may contact a portion of the second side surface 24hsb of the gate spacer 24. The second spacer 24b may be spaced apart from the at least one second horizontal bent portion 30e_AH. For example, the second spacer 24b may not contact the at least one second horizontal bent portion 30e_AH.

Hereinafter, various modified examples of components of the above-described semiconductor device 1 will be described. The various modified examples of the components of the above-described semiconductor device 1 will be described below based on the modified or replaced components. Also, components which may be modified or replaced will described below with reference to the drawings, but the components which may be modified or replaced may be combined with each other, or may be combined with other components described above and may be included in the semiconductor device 1 according to embodiment.

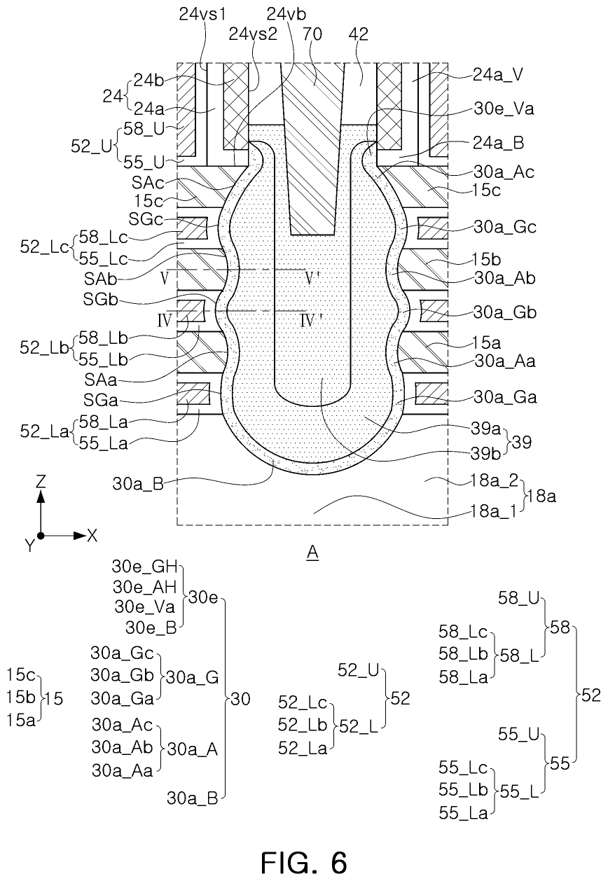

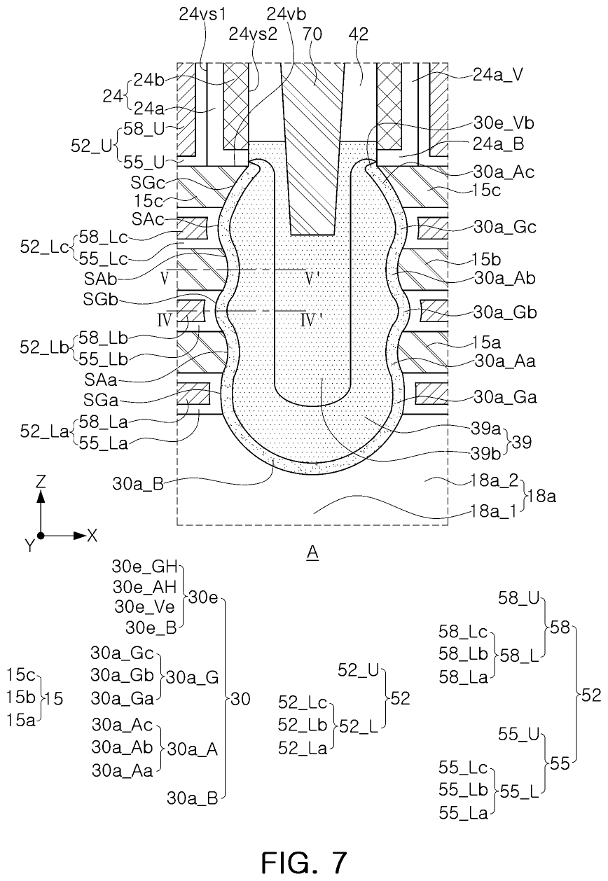

Various modified examples of the vertical bent portion 30e_V shown in FIG. 3 will be described with reference to FIGS. 6 and 7. FIG. 6 is an enlarged cross-sectional diagram illustrating a modified example of the semiconductor device of FIG. 1, according to an embodiment, and FIG. 7 is an enlarged cross-sectional view illustrating the modified example of the semiconductor device of FIG. 1, according to an embodiment. FIG. 6 is a cross-sectional view illustrating a modified component from the cross-sectional structure in FIG. 3, and FIG. 7 is a cross-sectional view illustrating a modified component from the cross-sectional structure in FIG. 3.

In a modified example, referring to FIG. 6, in the external side surface 24vs2 of the gate spacer 24 described with reference to FIG. 3, the vertical bent portion 30e_V (in FIG. 3) contacting a portion of the side surface of the first spacer 24a and spaced apart from the side surface of the second spacer 24b may be modified to a vertical bent portion 30e_Va bent and extending from the upper active blocking portion 30a_Ac, contacting the side surface of the first spacer 24a and a portion of the side surface of the second spacer 24b in the external side surfaces 24vs2 of the gate spacer 24.

In another modified example, referring to FIG. 7, the vertical bent portion 30e_V (in FIG. 3) contacting at least a half of the side surface of the first spacer 24a in the external side surface 24vs2 of the gate spacer 24 and spaced apart from the side surface of the second spacer 24b may be modified to a vertical bent portion 30e_Vb bent and extending from the upper active blocking portion 30a_Ac and contacting less than a half of the side surface of the first spacer 24a in the external side surface 24vs2 of the gate spacer 24.

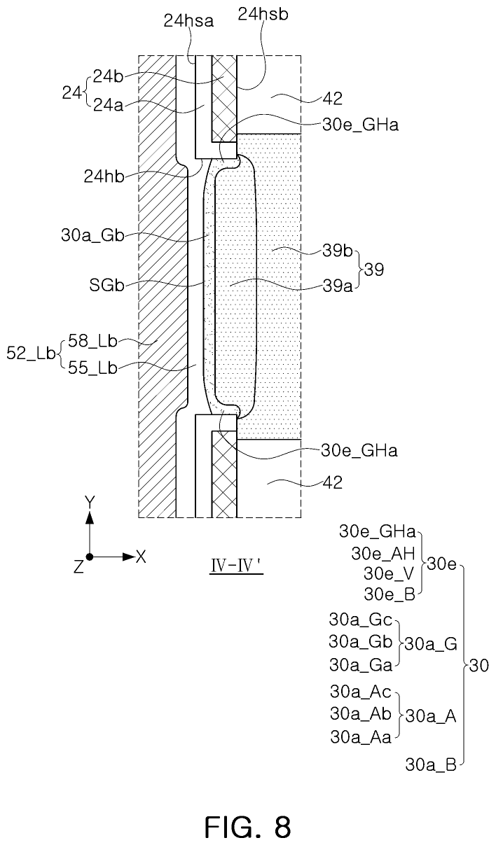

In the description below, a modified example of the first horizontal bent portion 30e_GH shown in FIG. 4 will be described with reference to FIG. 8. FIG. 8 is an enlarged cross-sectional view of a modified example of the semiconductor device of FIG. 1 in a plan view, illustrating a modified component of FIG. 4, according to an embodiment.

In a modified example, referring to FIG. 8, the at least one first horizontal bent portion 30e_GH (in FIG. 4) contacting the third side surface 24hb of the gate spacer 24 and spaced apart from the second side surface 24hsb of the gate spacer 24 may be modified to a first horizontal bent portion 30e_GHa extending from a portion contacting the third side surface 24hb of the gate spacer 24 and disposed on a portion of the second side surface 24hsb of the gate spacer 24. The first horizontal bent portion 30e_GHa may be spaced apart from the second spacer 24b. For example, the first horizontal bent portion 30e_GHa may not contact the second spacer 24b.

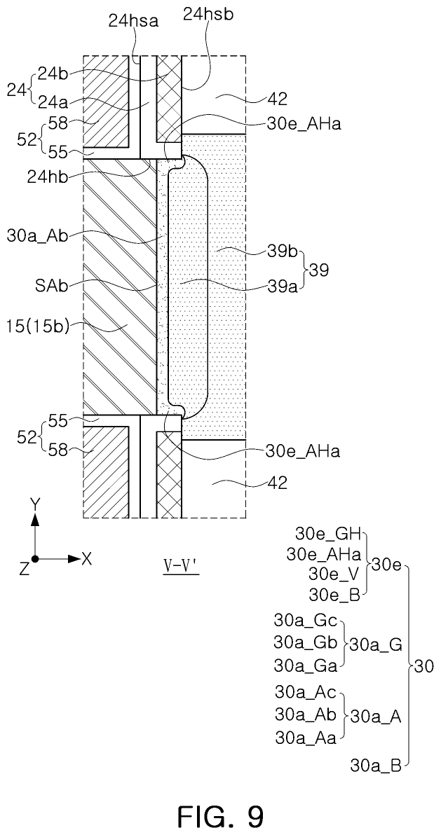

In the description below, a modified example of the second horizontal bent portion 30e_AH shown in FIG. 5 will be described with reference to FIG. 9. FIG. 9 is an enlarged cross-sectional view of a modified example of the semiconductor device of FIG. 1 in a plan view, illustrating a modified component of FIG. 5, according to an embodiment.

In a modified example, referring to FIG. 9, the at least one second horizontal bent portion 30e_AH (in FIG. 5) contacts the third side surface 24hb of the gate spacer 24 and spaced apart from the second side surface 24hsb of the gate spacer 24 may be modified to a second horizontal bent portion 30e_AHa extending from a portion contacting the third side surface 24hb of the gate spacer 24 and disposed on a portion of the second side surface 24hsb of the gate spacer 24. The second horizontal bent portion 30e_AHa may be spaced apart from the second spacer 24b. For example, the second horizontal bent portion 30e_AHa may not contact the second spacer 24b.

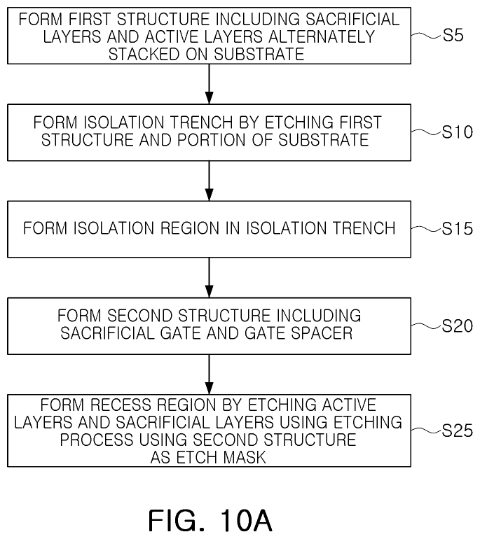

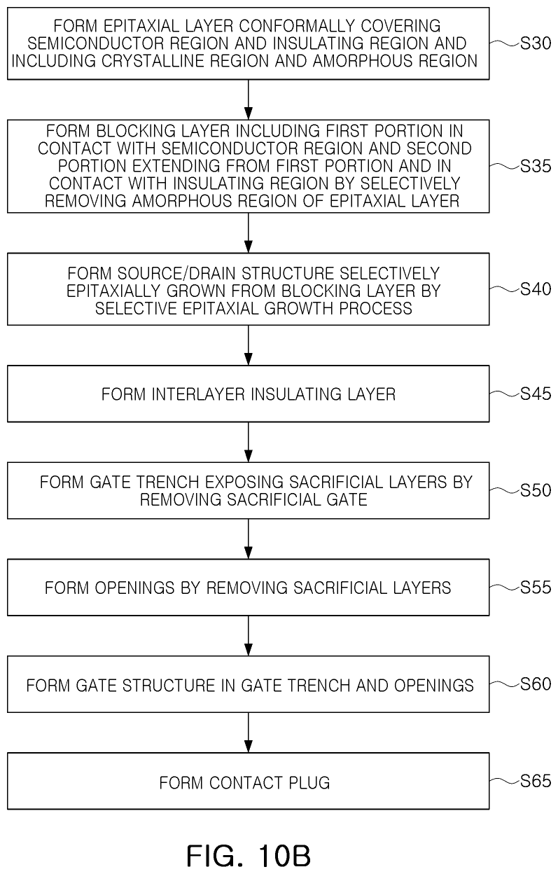

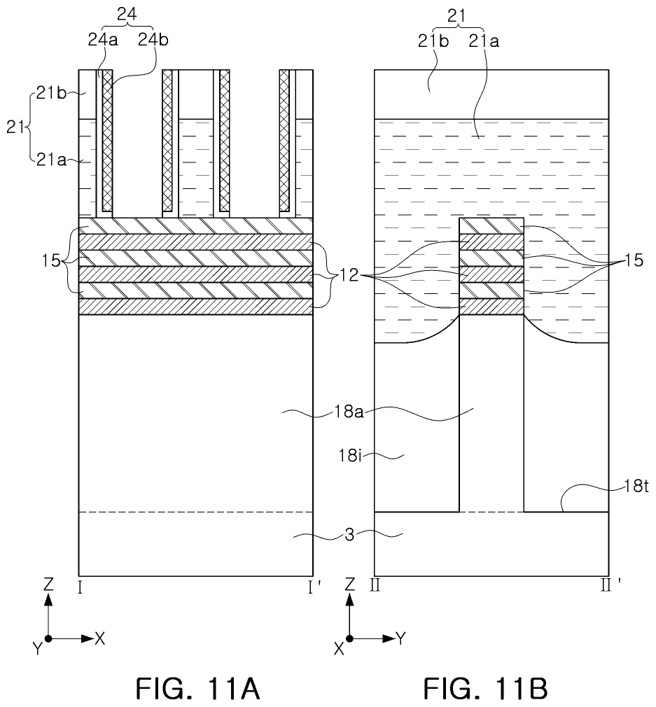

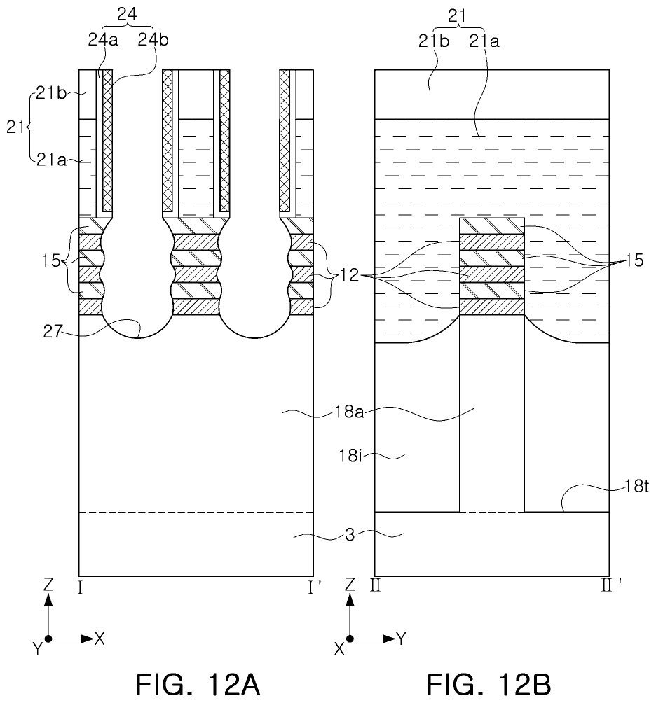

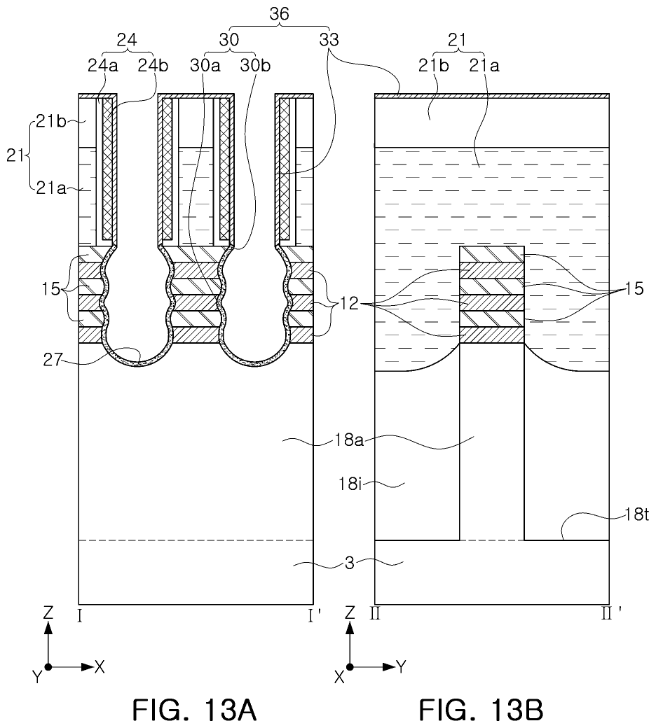

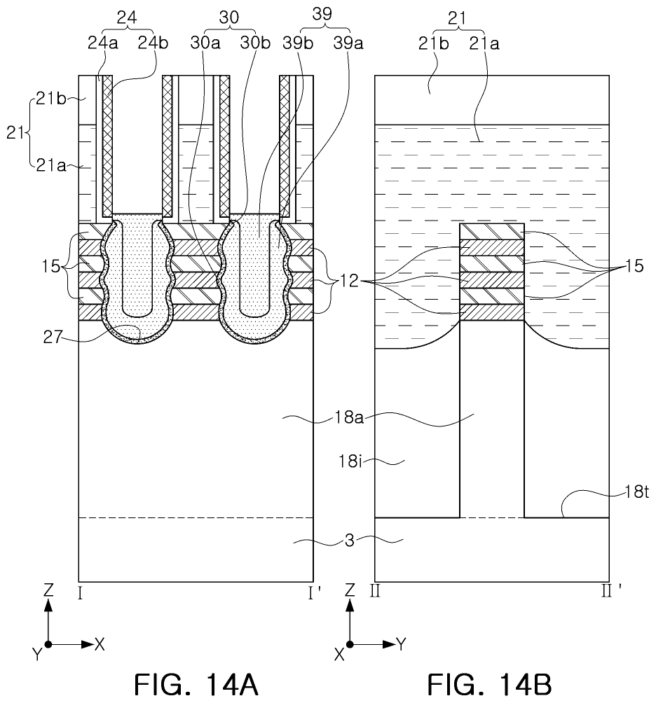

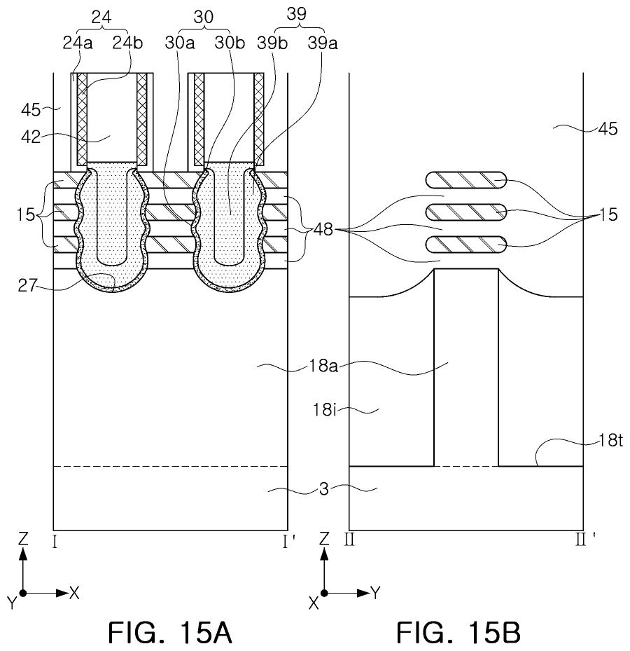

In the description below, an embodiment of a method of forming a semiconductor device according to an embodiment will be described with reference to FIGS. 10A, 10B, and 11A-11B to 15A-15B. FIGS. 10A and 10B are flow charts illustrating an example of a method of manufacturing a semiconductor device, according to an embodiment, and FIGS. 11A-11B to 15A-15B are cross-sectional views illustrating a method of forming the semiconductor device shown in FIG. 1 taken along lines I-I′ and II-II′, respectively, according to embodiments.

Referring to FIGS. 10A and 11A-11B, a first structure 12 and 15 including sacrificial layers 12 and active layers 15 alternately stacked on a substrate 3 may be formed (S5). In the first structure 12 and 15, a lowermost layer among the active layers 15 and the sacrificial layers 12 may be a sacrificial layer, and an uppermost layer may be an active layer. The sacrificial layers 12 may be replaced with the lower gate portions 52L as described with reference to FIGS. 2A and 3 through a subsequent process. Each of the active layers 15 may be formed as a first material layer using an epitaxial process, and each of the sacrificial layers 12 may be formed as a second material layer different from the first material layer using the epitaxial process. The first material layer of the active layers 15 may include a silicon layer, and the second material layer of the sacrificial layers 12 may include at least one of a SiGe layer and a Ge layer.

An isolation trench 18t may be formed by etching the first structure 12 and 15 and a portion of the substrate 3 (S10). An active region 18a formed below the first structure 12 and 15 may be defined by the isolation trench 18t. The active region 18a may have a bar shape or a line shape extending in the first horizontal direction X.

An isolation region 18i filling the isolation trench 18t and exposing side surfaces of the first structure 12 and 15 may be formed (S15). The isolation region 18i may be formed of an insulating material. For example, the isolation region 18i may include a low-κ dielectric, silicon oxide, silicon nitride, or another oxide or nitride compound, not being limited thereto.

A second structure 21 and 24 including a sacrificial gate 21 and a gate spacer 24 may be formed (S20).

The sacrificial gate 21 may intersect the first structure 12 and 15 and the active region 18a, and may extend in the second horizontal direction Y. The sacrificial gate 21 may include a first sacrificial gate 21a and a second sacrificial gate 21b stacked in order. The gate spacer 24 may be formed on a side surface of the sacrificial gate 21. The forming the gate spacer 24 may include conformally forming a first layer, conformally forming a second layer having a greater thickness than the thickness of the first layer, and anisotropically etching the first and second layers. The anisotropically etched first layer may be formed as a first spacer 24a, and the anisotropically etched second layer may be formed as a second spacer 24b.

Referring to FIGS. 10A and 12, a recess region 27 may be formed by etching the active layers 15 and the sacrificial layers 12 using an etching process using the second structure 21 and 24 as an etch mask (S25). Depending on a difference in etching rates between the active layers 15 and the sacrificial layers 12, at least a portion of the side surfaces of the remaining active layers 15 may have an outwardly curved shape toward the recess region 27, and at least a portion of the side surfaces of the remaining sacrificial layers 12 may have an inwardly curved shape from the recess region 27.

According to an embodiment, the side surfaces of the active layers 15, the side surfaces of the sacrificial layers 12, and the active region 18a (e.g., the upper surface thereof) exposed by the recess region 27 may be referred to as semiconductor regions 12, 15, and 18a, and the surface of the gate spacer 24, the upper surface of the second sacrificial gate 21b, and the upper surface 18s (in FIG. 2C) of the isolation region 18i (in FIG. 2C) may be referred to as insulating regions 21b and 24 (18s in FIG. 2C).

Referring to FIGS. 10B and 13, an epitaxial layer 36 conformally covering the semiconductor regions 12, 15, and 18a and the insulating regions 21b, 24 and 18s (in FIG. 2C), and including a crystalline region 30 and an amorphous region 33 may be formed (S30).

The epitaxial layer 36 may have a thickness ranging from about 1 nm to about 5 nm.

The crystalline region 30 may contact the semiconductor regions 12, 15, and 18a, may be disposed on the semiconductor regions 12, 15, and 18a, and may extend to the insulating regions 24 and 18s (in FIG. 2C) adjacent to the semiconductor regions 12, 15, and 18a. The amorphous region 33 may extend from the crystalline region 30 and may be disposed on the insulating regions 21b, 24, and 18s (in FIG. 2C).

The crystalline region 30 may include a first portion 30a contacting the semiconductor regions 12, 15, and 18a and a second portion 30b extending from the first portion 30a to the insulating regions 24 and 18s (in FIG. 2C) adjacent to the semiconductor regions 12, 15, and 18a.

In the epitaxial layer 36, the crystalline region 30 may be formed of crystalline silicon, and the amorphous region 33 may be formed of amorphous silicon.

The crystalline region 30 may be included in the blocking layer 30 of one of embodiments described with reference to FIGS. 1 to 9. For example, in the crystalline region 30, the first portion 30a may be included in the plurality of active blocking portions 30a_A, the plurality of gate blocking portions 30a_G, and the lower blocking portion 30a_B as illustrated in FIG. 3, and the second portion 30b may be included in the at least one bent portion 30e as illustrated in FIG. 2C and FIGS. 3 to 5.

Referring to FIGS. 10B and 14, by selectively removing the amorphous region 33 (in FIG. 13) of the epitaxial layer 36 (in FIG. 13), the blocking layer 30 may be formed to include the first portion 30a contacting the semiconductor regions 12, 15, and 18a and the second portion 30b extending from the first portion 30a and contacting the insulating regions 24 and 18s (in FIG. 2C) (S35). That is, the crystalline region 30 in FIG. 13 may remain and may be formed as the blocking layer 30.

A source/drain structure 39 selectively epitaxially grown from the blocking layer 30 may be formed by a selective epitaxial growth process (S40). The source/drain structure 39 may include a first source/drain epitaxial layer 39a selectively epitaxially grown from the blocking layer 30 and a second source/drain epitaxial layer 39b selectively epitaxially grown from the first source/drain epitaxial layer 39a. The first source/drain epitaxial layer 39a may be formed of a first SiGe material, and the second source/drain epitaxial layer 39b may be formed of a second SiGe material having a composition different from that of the first SiGe material. A Ge concentration of the second SiGe material may be higher than a Ge concentration of the first SiGe material.

Referring to FIGS. 10B and 15, an interlayer insulating layer 42 (in FIGS. 2A and 2C) may be formed (S45). The forming the interlayer insulating layer 42 (in FIGS. 2A and 2C) may include forming an insulating layer on the substrate 3 formed up to the source/drain structure 39 and planarizing the insulating layer. While forming the interlayer insulating layer 42 (in FIGS. 2A and 2C) or after forming the interlayer insulating layer 42 (in FIGS. 2A and 2C), the second sacrificial gate 21B (in FIG. 14) may be removed, and the level of the gate spacer 24 may be reduced.

A gate trench 45 exposing the sacrificial layers 12 (in FIG. 14) may be formed by removing the sacrificial gate 21 (in FIG. 14) (S50). The removing the sacrificial gate 21 (in FIG. 14) may include exposing the first sacrificial gate 21 (in FIG. 14) by removing the second sacrificial gate (21b in FIG. 14) while forming the interlayer insulating layer 42 (in FIGS. 2A and 2C) or after forming the interlayer insulating layer 42 (in FIGS. 2A and 2C), and removing the exposed first sacrificial gate 21a (in FIG. 14).

By removing the sacrificial layers 12 (in FIG. 14), openings 48 may be formed (S55). A portion of the blocking layer 30 may be exposed while removing the sacrificial layers 12 (in FIG. 14). The source/drain structure 39 may not be exposed by the openings 48 due to the blocking layer 30.

Referring to FIGS. 1 to 5, in addition to FIG. 10B, a gate structure 52 may be formed in the gate trench 45 (in FIG. 15) and the openings 48 (in FIG. 15) (S60). The gate structure 52 may fill the gate trench 45 (in FIG. 15) and the openings 48 (in FIG. 15), and may include the gate dielectric layer 55 and the gate electrode 58 described with reference to FIGS. 1 to 5. A contact plug 70 may be formed (S65). The contact plug 70 may penetrate through the interlayer insulating layer 42 and may be electrically connected to the source/drain structure 39.

According to the aforementioned embodiments, a semiconductor device including a blocking layer which may prevent a leakage current that may be generated between a gate electrode and a source/drain structure or electrical short that may be generated between a gate electrode and a source/drain structure may be provided.

While the embodiments have been illustrated and described above, it will be configured as apparent to those skilled in the art that modifications and variations could be made without departing from the scope of the present disclosure as defined by the appended claims.

What is claimed is:

1. A semiconductor device, comprising:
an active region comprising a first portion and a second portion;
an isolation region on a side surface of the active region;
a plurality of active layers stacked and spaced apart from each other in a vertical direction, and on the first portion of the active region;
an epitaxial structure disposed on the second portion of the active region, connected to the plurality of active layers, and overlapping the isolation region in the vertical direction;
a gate structure surrounding the plurality of active layers; and
a gate spacer on a side surface of the gate structure,
wherein the epitaxial structure comprises a blocking layer and a source/drain structure on the blocking layer, and
wherein the blocking layer comprises:
a plurality of active blocking portions contacting the plurality of active layers, respectively; and
at least one first bent portion bent and extending from at least one of the plurality of active blocking portions and contacting the gate spacer.

2. The semiconductor device of claim 1, wherein the at least one first bent portion comprises a vertical bent portion extending from an upper active blocking portion among the plurality of active blocking portions and contacting the gate spacer.

3. The semiconductor device of claim 2,
wherein the gate spacer comprises an internal side surface contacting the gate structure, an external side surface opposite to the internal side surface, and a lower surface contacting an upper surface of the upper active blocking portion, and
wherein the vertical bent portion contacts a portion of the external side surface of the gate spacer.

4. The semiconductor device of claim 3,
wherein the plurality of active layers comprise an upper active layer,
wherein the gate spacer comprises a first spacer and a second spacer,
wherein the first spacer comprises a vertical portion between the second spacer and the gate structure, and a lower portion between the second spacer and the upper active layer, and
wherein the vertical bent portion contacts the first spacer.

5. The semiconductor device of claim 4, wherein the vertical bent portion is spaced apart from the second spacer.

6. The semiconductor device of claim 5, wherein the source/drain structure contacts the first spacer and the second spacer.

7. The semiconductor device of claim 5,
wherein the gate structure comprises:
a plurality of lower gate portions below the plurality of active layers, respectively; and
an upper gate portion above an upper active layer among the plurality of active layers,
wherein the blocking layer further comprises a plurality of gate blocking portions contacting the plurality of lower gate portions, respectively,
wherein the plurality of gate blocking portions comprise a first gate blocking portion, and
wherein, in a plan view, the blocking layer further comprises a first horizontal bent portion bent and extending from the first gate blocking portion and contacting the gate spacer.

8. The semiconductor device of claim 7,
wherein the gate structure comprises a gate dielectric layer and a gate electrode on the gate dielectric layer,
wherein, in the plan view, the gate spacer comprises a first side surface, a second side surface opposite to the first side surface, and a third side surface extending from end portions of the first and second side surfaces and connecting the end portions to each other,
wherein the first side surface of the gate spacer contacts the gate dielectric layer,
wherein the third side surface of the gate spacer contacts the gate dielectric layer, the first gate blocking portion, and the first horizontal bent portion, and
wherein the second side surface of the gate spacer contacts the source/drain structure.

9. The semiconductor device of claim 8, wherein the second side surface of the gate spacer is spaced apart from the first gate blocking portion and the first horizontal bent portion.

10. The semiconductor device of claim 8, wherein the second side surface of the gate spacer contacts the first horizontal bent portion and the source/drain structure.

11. The semiconductor device of claim 1,
wherein the active blocking portions comprise a first active blocking portion contacting a first active layer among the plurality of active layers, and
wherein, in a plan view, the at least one first bent portion further comprises a horizontal bent portion bent and extending horizontally from the first active blocking portion and contacting the gate spacer.

12. The semiconductor device of claim 11,
wherein the gate structure comprises a gate dielectric layer and a gate electrode on the gate dielectric layer,
wherein, in the plan view, the gate spacer comprises a first side surface, a second side surface opposite to the first side surface, and a third side surface extending from end portions of the first and second side surfaces and connecting the end portions to each other,
wherein the first side surface of the gate spacer contacts the gate dielectric layer,
wherein the third side surface of the gate spacer contacts the first active layer, the first active blocking portion, and the horizontal bent portion, and
wherein the second side surface of the gate spacer contacts the source/drain structure.

13. The semiconductor device of claim 12, wherein the second side surface of the gate spacer is spaced apart from the first active blocking portion and the horizontal bent portion.

14. The semiconductor device of claim 12, wherein the second side surface of the gate spacer contacts the horizontal bent portion and the source/drain structure.

15. The semiconductor device of claim 1,
wherein the blocking layer further comprises a lower blocking portion between the active region and the source/drain structure,
wherein the blocking layer further comprises a lower bent portion bent and extending from the lower blocking portion,
wherein the lower bent portion contacts an upper surface of the isolation region, and
wherein a lower end portion of the lower bent portion is at a lower level than the lower blocking portion.

16. The semiconductor device of claim 1,
wherein the blocking layer comprises a silicon layer,
wherein the source/drain structure comprises a first source/drain epitaxial layer and a second source/drain epitaxial layer on the first source/drain epitaxial layer,
wherein the first source/drain epitaxial layer includes a first silicon germanium layer, and
wherein the second source/drain epitaxial layer includes a second silicon germanium layer different from the first silicon germanium layer.

17. A semiconductor device, comprising:
an active region comprising a first portion and a second portion;
an isolation region on a side surface of the active region;
a plurality of active layers stacked and spaced apart from each other in a vertical direction and on the first portion of the active region;
an epitaxial structure disposed on the second portion of the active region, connected to the plurality of active layers, and overlapping the isolation region in the vertical direction;
a gate structure surrounding the plurality of active layers; and
a gate spacer on a side surface of the gate structure,
wherein the gate structure includes:
a plurality of lower gate portions below the plurality of active layers, respectively; and
an upper gate portion on an upper active layer among the plurality of active layers,
wherein the epitaxial structure comprises a blocking layer and a source/drain structure on the blocking layer, and
wherein the blocking layer comprises:
a lower blocking portion contacting the second portion of the active region;
a plurality of active blocking portions contacting the plurality of active layers, respectively;
a plurality of gate blocking portions contacting the lower gate portions, respectively; and
at least one bent portion bent and extending from at least one of the plurality of active blocking portions, the plurality of gate blocking portions, and the lower blocking portion, and contacting the gate spacer.

18. The semiconductor device of claim 17,
wherein the blocking layer comprises a silicon layer, and
wherein the source/drain structure comprises a silicon germanium layer.

19. A semiconductor device, comprising:
an active region comprising a first portion and a second portion;
a plurality of active layers stacked and spaced apart from each other in a vertical direction and on the first portion of the active region;
an epitaxial structure on the second portion of the active region and connected to the plurality of active layers;
a gate structure surrounding the plurality of active layers; and
a gate spacer on a side surface of the gate structure,
wherein the gate structure comprises:
a plurality of lower gate portions below the plurality of active layers, respectively; and
an upper gate portion above an upper active layer among the plurality of active layers,
wherein the epitaxial structure comprises a blocking layer and a source/drain structure on the blocking layer, and
wherein the blocking layer comprises:
a lower blocking portion contacting the second portion of the active region;
a plurality of active blocking portions contacting the plurality of active layers, respectively;
a plurality of gate blocking portions contacting the lower gate portions, respectively; and
at least one bent portion bent and extending horizontally from at least one of the plurality of active blocking portions and the plurality of gate blocking portions and contacting the gate spacer.

20. The semiconductor device of claim 19,
wherein the blocking layer comprises a silicon layer doped with at least one of carbon (C), oxygen (O), nitrogen (N), and fluorine (F),
wherein the source/drain structure comprises a silicon germanium layer having p-type conductivity, and
wherein a thickness of the blocking layer is in a range of about 1 nm to about 5 nm.
